(19) United States
(12) Patent Application Publication
(10) Pub. No.: US 2026/0327838 A1
(43) Pub. Date: Oct. 22, 2026

(54) METHOD AND APPARATUS TO CONTROL UNIFORMITY OF ELECTROCHEMICALLY DEPOSITED METALS AND ALLOYS

(71) Applicant: Applied Materials, Inc., Santa Clara, CA (US)

(72) Inventors: Dmitry LUBOMIRSKY, Cupertino, CA (US); Pranav Vijay GADRE, Santa Clara, CA (US); Benjamin TOTH, Santa Clara, CA (US); Kailash VENKATRAMAN, Santa Clara, CA (US); Prakash MANUR, Santa Clara, CA (US); Ellie Y. YIEH, San Jose, CA (US)

(21) Appl. No.: 19/649,550

(22) Filed: Apr. 16, 2026

Related U.S. Application Data
(60) Provisional application No. 63/792,255, filed on Apr. 21, 2025.
(60) Provisional application No. 63/791,307, filed on Apr. 18, 2025.

(51) Int. Cl. C25D 5/02; H10P 14/47

(52) U.S. Cl. CPC C25D 5/022; H10P 14/47

(57) ABSTRACT

Electroplating components and methods of electroplating are provided. In one aspect, an electroplating chamber is provided. The electroplating chamber includes a vessel comprising one or more walls, a plating head assembly positioned to hold a substrate in a face-down orientation, and a pattern mask diffuser. The pattern mask diffuser includes a body that includes an array of diffuser apertures formed therethrough. The electroplating chamber further includes an actuator that is configured to translate the pattern mask diffuser in an X-Y plane. The electroplating chamber further includes a pixelated anode assembly comprising a plurality of individual anode members, wherein each of the plurality of anode members is independently biasable.

### CROSS-REFERENCE TO RELATED APPLICATIONS

This application claims the benefit of U.S. Provisional Patent Application Serial No. 63/791,307, filed Apr. 18, 2025, and U.S. Provisional Patent Application Serial No. 63/792,255, filed Apr. 21, 2025, both of which are incorporated by reference herein in their entirety.

### BACKGROUND

### Field

Embodiments of the present disclosure generally relate to methods, components, and apparatuses for semiconductor manufacturing. More specifically, the present disclosure generally relates to electroplating components and other semiconductor processing equipment.

### Description of the Related Art

Microelectronic devices, such as semiconductor devices, are fabricated on and/or in wafers or workpieces. A typical wafer plating process involves depositing a metal seed layer onto the surface of the wafer via vapor deposition. A photoresist may be deposited and patterned to expose the seed layer. The wafer is then moved into the vessel of an electroplating processor where electric current is conducted through an electrolyte to the wafer, to apply a blanket layer or patterned layer of a metal or other conductive material onto the seed layer. Examples of conductive materials include permalloy, gold, silver, copper, cobalt, tin, nickel, and alloys of these metals. Subsequent processing steps form components, contacts, and/or conductive lines on the wafer. Many aspects of an electroplating process may impact process uniformity, such as irregularities in the electric field due to pattern variations, mass-transfer rates, as well as other process and component parameters. Even minor discrepancies across a substrate may impact downline finishing processes.

Conventional electroplating chambers and methods lead to high Total Thickness Variation (TTV) when processing large die patterns that include significant area density variations and also have a pattern perimeter that does not extend to the edge of the wafer. Controlling the TTV using conventional means often requires low plating rates, which results in low throughput. Designs that yield lower TTV enable higher plating rates and therefore higher wafer throughput, which is a desirable factor in producing microelectronic devices.

Thus, there is a need for improved systems and methods that can be used to produce high quality devices and structures.

### SUMMARY

In one aspect, an electroplating chamber is provided. The electroplating chamber includes a vessel, a plating head assembly configured to hold a substrate in a face-down orientation, a pixelated anode assembly including a plurality of individual anode members that are independently biasable, a pattern mask diffuser disposed between the plating head assembly and the pixelated anode assembly, and an actuator configured to translate the pattern mask diffuser in an X-Y plane during plating. The pattern mask diffuser may include a body having an array of apertures formed therethrough.

Embodiments may include one or more of the following. A controller configured to coordinate translation of the pattern mask diffuser with power delivered to individual anode members or groups of anode members. The plating head assembly is movable in the X-Y plane relative to the pattern mask diffuser. The plating head assembly includes a substrate support and a contact ring disposed on the substrate support. A first collimator plate positioned to restrict horizontal dispersion of an electric field traveling toward the plating head assembly. An actuator configured to translate the first collimator plate in the X-Y plane. A second collimator plate positioned between the pixelated anode assembly and the first collimator plate. The first collimator plate includes a first plurality of elongated conduits and the second collimator plate includes a second plurality of elongated conduits, and the second collimator plate is positioned below the first collimator plate such that longitudinal axes of the first plurality of elongated conduits are substantially aligned with longitudinal axes of the second plurality of elongated conduits. An ionic membrane dividing the vessel into an anolyte compartment and a catholyte compartment, wherein the pixelated anode assembly is disposed in the anolyte compartment and the pattern mask diffuser is disposed in the catholyte compartment. The first collimator plate is disposed in the catholyte compartment and the second collimator plate is disposed in the anolyte compartment.

In another aspect, an electroplating chamber is provided. The electroplating chamber includes a vessel, a substrate holder configured to hold a substrate in a face-down orientation over a plating region, an ionic membrane dividing the vessel into an anolyte compartment and a catholyte compartment, a pixelated anode assembly disposed in the anolyte compartment beneath the ionic membrane, and a flow system configured to direct catholyte flow across a substrate-facing side of the ionic membrane and toward the substrate during plating.

Embodiments may include one or more of the following. A first support structure disposed in the anolyte compartment adjacent a lower side of the ionic membrane and second support structure disposed in the catholyte compartment adjacent an upper side of the ionic membrane. The first support structure and the second support structure each include a collimator plate having a plurality of conduits configured to reduce horizontal electric-field dispersion. The flow system includes a pump configured to produce tangential flow of catholyte across the substrate. An anolyte flow gap is defined between the ionic membrane and a support structure adjacent the pixelated anode assembly, the anolyte flow gap being sized to permit clearing of gas bubbles generated at the pixelated anode assembly. The pixelated anode assembly includes a plurality of anode members disposed in pockets defined by a body, each pocket contains a consumable metal source, and each anode member is electrically coupled to a printed circuit board through a respective pin assembly. The vessel and the substrate holder are arranged such that the substrate is tilted relative to horizontal during plating.

In another aspect, a method of electroplating a substrate is provided. The method includes positioning a substrate in a face-down orientation opposite a pixelated anode assembly having a plurality of independently biasable anode members, disposing a pattern mask diffuser having an array of apertures between the substrate and the pixelated anode assembly, applying plating current through the pixelated anode assembly to deposit metal on the substrate, and translating the pattern mask diffuser relative to the substrate in an X-Y plane during application of the plating current.

Embodiments may include one or more of the following. Varying power delivered to individual anode members or groups of anode members in coordination with translation of the pattern mask diffuser. Translating the pattern mask diffuser includes moving the array of apertures through a sequence of offset positions relative to corresponding anode members during a plating cycle.

In another aspect, a non-transitory computer readable medium has stored thereon instructions, which, when executed by a processor, causes the process to perform operations of the above apparatus and/or method.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A illustrates a schematic plan view of a wafer that includes multiple large die patterns that include area density variations.

FIG. 1B illustrates a schematic close-up plan view of one of the multiple large die patterns that includes a plurality of area density variations.

FIG. 2 illustrates a schematic side view of an electroplating system in accordance with one or more embodiments of the present disclosure.

FIG. 3 illustrates a schematic plan view of a pixelated anode assembly in accordance with one or more embodiments of the present disclosure.

FIG. 4A illustrates a schematic plan view of a pattern mask diffuser in accordance with one or more embodiments of the present disclosure.

FIGS. 4B-4C are schematic plan views of a pixel features of the pattern mask diffuser in accordance with one or more embodiments of the present disclosure.

FIGS. 5A-5D illustrate schematic plan views of the movement of a diffuser assembly relative to a pixelated anode assembly during various stages of a plating process in accordance with one or more embodiments of the present disclosure.

FIGS. 6A-6B illustrate isometric views of a portion of an electroplating system in accordance with one or more embodiments of the present disclosure.

FIG. 7 illustrates a schematic side view of a portion of an electroplating system in accordance with one or more embodiments of the present disclosure.

FIG. 8 illustrates a schematic side view of a pixelated anode assembly in accordance with one or more embodiments of the present disclosure.

FIGS. 9A-9D illustrates a schematic side view of a portion of an electroplating system in accordance with one or more embodiments of the present disclosure.

FIG. 10 illustrates a schematic side view of a portion of an electroplating system in accordance with one or more embodiments of the present disclosure.

FIG. 11 illustrates a schematic side view of a portion of an electroplating system in accordance with one or more embodiments of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to a semiconductor processing chamber, and more particularly, an electroplating chamber assembly that includes a chamber geometry configured to improve an electroplating deposition uniformity within the processing chamber, and related methods. Embodiments of the present disclosure more particularly relate to an electroplating system and methods of processing wafers that are adapted to deposit a layer on multiple large die patterns.

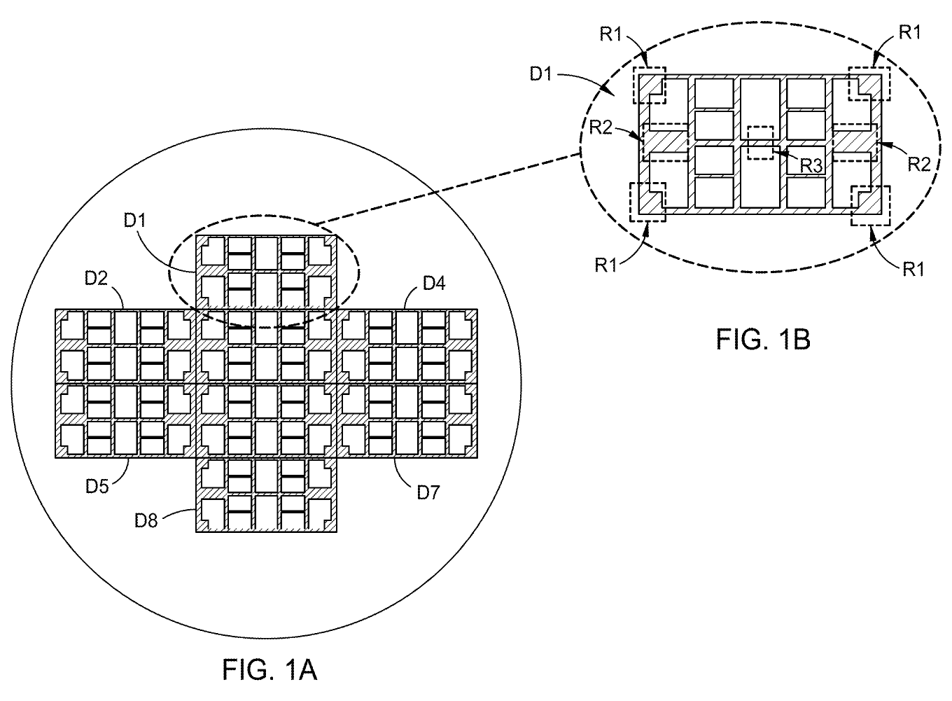

FIG. 1A is a plan view of a wafer that includes multiple large die patterns that include area density variations within regions of each die pattern. As shown in FIG. 1A, the wafer includes eight die patterns D1-D8 that are positioned, oriented and exposed on a surface of a wafer. In some configurations, the dark colored regions of the die patterns include one or more exposed features that include one or more metal layers that have a varying pattern density, while the white or uncolored regions will typically include an unpatterned photoresist or dielectric material.

FIG. 1B is a close-up plan view of a first die pattern D1 of the plurality of die patterns that includes a plurality of area density variations. In one example, the first die pattern D1 includes multiple regions that can be characterized as falling within one of three different average area densities R1-R3. In the examples provided herein, it is assumed that each of die patterns D1-D8 include two or more regions that have different area densities, such as one or more regions that include a first area density R1, one or more regions that include a second area density R2, and one or more regions that include a third area density R3, wherein the first area density R1 is less than the second area density R2, which is less than the third area density R3. Due to the variation in area density, the plating rate and thus TTV within the different area density regions during a plating process will have significant variations across the die patterns.

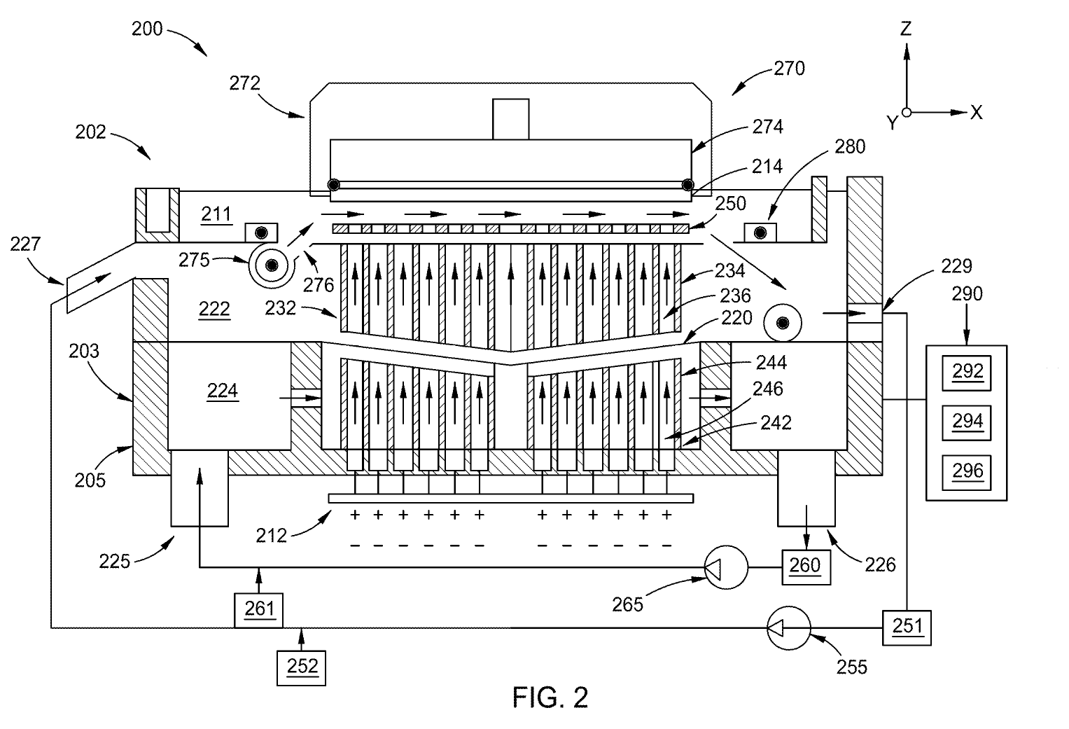

Certain embodiments of the present disclosure overcome the challenges experienced in the industry when trying to plate metals within die patterns similar to the first die pattern D1 by incorporating components that selectively shield various regions of a wafer and die patterns from the electric field produced during electroplating operations. The apparatus includes one or more of a pixelated anode assembly (i.e., item 212 in FIG. 2), a collimator with X-Y tuning, a pattern mask diffuser with X-Y adjustment, and the substrate with X-Y adjustment. For example, embodiments of the present disclosure may use a pixelated anode with independent power delivery to each tile or pixel of the pixelated anode assembly. The anode tiles can be arranged in a rectangular pattern or array. Each anode tile can have a quadratic rectangular or hexagonal shape. An upper collimator plate (i.e., item 232 in FIG. 2) or a bundle of separated tubes can be positioned between the pixelated anode and the face-down panel or wafer. The upper collimator plate or tubes can be positioned above a cation exchange membrane in a catholyte compartment and/or optionally in the anolyte compartment. A thief electrode (i.e., item 280 in FIG. 2) can be positioned adjacent to the panel or wafer and have a shape corresponding to the edges of the panel or wafer. A diffuser plate (i.e., item 250 in FIG. 2) can be positioned in between the upper collimator plate and the panel or wafer. The diffuser plate has a plurality of openings, for example, square openings with each opening located within the projected pattern or lateral extents of each anode tile. The X-Y movement of the diffuser plate relative to the anode tiles and optionally, the X-Y movement of the panel or wafer can be software controlled and coordinated in time with the power delivered to each tile to selectively shield various regions of a wafer and die patterns from the electric field produced during electroplating operations.

In one or more embodiments, the diffuser plate is omitted. For example, if the number of anode tiles is large enough and the anode tile size is small, the diffuser may be omitted. In this example, the upper collimator is movable in the X-Y plane relative to the lower collimator (i.e., item 244 in FIG. 2), which provides a similar effect to moving the diffuser. The X-Y movement of the upper collimator can be software controlled depending on the die pattern layout. The X-Y movement of the upper collimator can be coordinated with the power setting on individual anode tiles or a group of anode tiles.

In one or more embodiments, a method of electroplating includes omitting the pattern mask diffuser 250 and controlling plating uniformity by translating the upper collimator plate 232 relative to the lower collimator plate 242 while independently controlling power delivered to anode members 305 of the pixelated anode assembly 212.

In one or more embodiments, a deplating process is performed by switching the polarity at the anode tiles and the panel or wafer.

In one or more embodiments, the upper collimator is movable in the X-Y plane relative to the lower collimator and the diffuser is also movable in the X-Y plane while the panel or wafer remains stationary. The X-Y movement of the upper collimator and the diffuser can be software controlled depending on the die pattern layout. The X-Y movement of the upper collimator and the diffuser can be coordinated with the power setting on individual anode tiles or a group of anode tiles.

For example, embodiments of the present disclosure may utilize a pixelated anode assembly in conjunction with a shielding assembly that includes a pattern mask diffuser that includes shielded areas that correspond with and minimize the flow of the plating current to sparse regions of a die pattern and include open areas that allow an increased amount of the plating current to flow to the dense regions of the die patterns formed on the substrate that are to be plated during an electroplating process. The use of such a shielding assembly in conjunction with the pixelated anode assembly will enable plating rates within dense regions and sparse regions to be more uniform. Some embodiments may utilize a pattern mask diffuser that includes apertures aligned with dense regions that enable the electric field lines and plating current to pass through to the dense regions of the substrate, while a solid face of the pattern mask diffuser is used to reduce the field lines and plating current flowing to the sparse regions of the die pattern. Some embodiments may improve the Total Thickness Variation (TTV) and co-planarity of the deposited layer. Accordingly, the present technology may produce improved TTV and co-planarity of substrates during electroplating operations.

FIG. 2 is a side view of an electroplating system 200 in accordance with one or more embodiments of the present disclosure. The electroplating system 200 may include a plating cell 202, such as an electrochemical plating (ECP) cell, or other configuration known in the art. The plating cell 202 includes a vessel 203 having one or more walls 205.

The plating cell 202 is generally configured to fluidly isolate a pixelated anode assembly 212 of the plating cell 202 from a substrate 214 or plating electrode of the plating cell 202 via a membrane 220 positioned between the substrate 214 being plated and the pixelated anode assembly 212 of the plating cell 202. The membrane 220 divides the plating cell 202 into a lower compartment or anolyte compartment 224 containing the pixelated anode assembly 212 and a first liquid electrolyte (e.g., an anolyte), below the membrane 220, and an upper compartment or catholyte compartment 222 containing a second liquid electrolyte (e.g., a catholyte). Alternately, the membrane 220 may be omitted with the plating cell 202 having a single compartment holding a single electrolyte. Additionally, the plating cell 202 is generally configured to provide a first (supporting) solution (anolyte) to the anolyte compartment 224, for example, the volume between the upper surface of the pixelated anode assembly 212 and the lower surface of the membrane 220, and a second (plating) solution (catholyte) to the catholyte compartment 222, for example, the volume of fluid positioned above the upper surface of the membrane 220.

The plating cell 202 further includes an anolyte inlet 225 configured to deliver the anolyte to the plating cell 202 and an anolyte outlet 226 configured to remove anolyte from the plating cell 202. The anolyte inlet 225 is generally in fluid communication with an anolyte reservoir 260. A pump 265 is generally positioned between the anolyte reservoir 260 and the plating cell 202 and is configured for delivering the anolyte to the anolyte compartment 224 upon actuation. An additive dosing system 261 includes a plurality of components that are configured to provide one or more of the consumable and/or concentration level varying components of the anolyte to the recirculating anolyte.

The plating cell 202 further includes a catholyte inlet 227 configured to deliver the catholyte to the plating cell 202 and a catholyte outlet 229 configured to remove catholyte from the plating cell 202. The catholyte inlet 227 is generally in fluid communication with a catholyte reservoir 251. A pump 255 is generally positioned between the catholyte reservoir 251 and the plating cell 202 and is configured for delivering the catholyte to the catholyte compartment 222 upon actuation. An additive dosing system 252 includes a plurality of components that are configured to provide one or more of the consumable and/or concentration level varying components of the catholyte to the recirculating catholyte.

The plating cell 202 further includes a tangential flow pump 275 configured to deliver a high flow of the catholyte fluid across the surface of the substrate 214. The tangential flow pump 275, which is submersed with the catholyte compartment 222, includes a pump inlet 276 that is in fluid communication with the catholyte fluid received from or flowing from the catholyte inlet 227. A tangential flow pump 275 is generally positioned between the catholyte inlet 227 and the upper collimator plate 232, and configured to deliver a flow of the catholyte fluid within a gap formed between the pattern mask diffuser 250 and the surface of a substrate during a plating process. The tangential flow pump 275 can include a laterally extending roller (e.g., extending in the Y-direction) that is configured to cause a uniform lateral flow of fluid (e.g., X-direction) across the surface of the substrate 214.

The pixelated anode assembly 212 may include a soluble or insoluble anode. Generally, the pixelated anode assembly 212 includes a soluble anode that is consumed during the plating process. However, the pixelated anode assembly 212 can in some cases include an insoluble anode and is not consumed in the plating process. Suitable insoluble anodes include platinum and platinum metals including platinized titanium and niobium along with metal oxides, for example, iridium oxide and ruthenium oxide. Other anodes may also be used, for example, lead or carbon/graphite, and generally include a Group VIII metal, such as cobalt, nickel, ruthenium, rhodium, palladium, iridium, and platinum.

The membrane 220 is generally configured to prevent anode by-products from entering the catholyte compartment 222, thereby increasing plating performance by decreasing the number of defects present on the plated substrate. In addition, the membrane 220 generally prevents organic additive diffusion from the catholyte compartment 222 to the anolyte compartment 224. Preventing additive migration to the anolyte compartment 224 prevents additive breakdown and contamination generally caused by additive contact with the pixelated anode assembly 212. The membrane 220 may include an ion exchange membrane, such as a cation exchange membrane or an anion exchange membrane.

The membrane 220 may be one of many commercially available membranes. For example, Tokuyama Corporation manufactures and supplies various hydrocarbon membranes for electrodialysis and related applications under the trade name NEOSEPTA®. Perfluorinated cation membranes, which are stable to oxidation and useful for separating an insoluble anode from additives present in the catholyte solution, are generally available from DuPont Co as Nafion™ membranes, or from Asahi Glass Company (Japan) FLEMION® fluorinated ion exchange membranes.

The plating cell 202 further includes an upper collimator plate 232 positioned to restrict horizontal flow or dispersion of the electric field traveling from the pixelated anode assembly 212 to the surface of the substrate 214. In one or more embodiments, the upper collimator plate 232 is positioned in between the pixelated anode assembly 212 and the substrate 214. In one or more embodiments, the upper collimator plate 232 is positioned in between the membrane 220 and the substrate 214 in the catholyte compartment 222. In one or more other embodiments, the upper collimator plate 232 is positioned in the anolyte compartment 224. The upper collimator plate 232 includes a body having walls 234 defining and separating elongated conduits 236. The elongated conduits 236 are generally positioned adjacent to each other and have parallel or substantially parallel longitudinal axes. The longitudinal axes of the elongated conduits 236 may be positioned orthogonally to the plating surface of the substrate 214. As such, the longitudinal axes of the elongated conduits 236 are generally positioned orthogonal to an upper surface of the pixelated anode assembly 212 and the plating surface of the substrate 214. In one or more embodiments, the elongated conduits 236 are sized to fit within the boundary defined by a pixel of the pixelated anode assembly 212.

The upper collimator plate 232 is generally formed of an insulating material, such as plastic materials, PVDF, ceramics, polymer, composite material, or other electrically insulative material that is non-reactive with electrochemical plating solutions. In one or more other embodiments, the upper collimator plate 232 is replaced by a bundle of separated tubes.

In one or more embodiments, the upper collimator plate 232 is translatable or movable in the X-Y direction. Movement of the upper collimator plate 232 in the X-Y direction relative to the substrate 214 can direct the flow of plating fluid to targeted areas of the substrate 214.

The plating cell 202 can further include a lower collimator plate 242 positioned to restrict horizontal flow or dispersion of the electric field traveling from the pixelated anode assembly 212 to the surface of the substrate 214. In one or more embodiments, the lower collimator plate 242 is positioned in between the pixelated anode assembly 212 and the substrate 214 below the upper collimator plate 232. The lower collimator plate 242 is generally formed of an insulating material, such as plastic materials, PVDF, ceramics, polymer, composite material, or other electrically insulative material that is non-reactive with electrochemical plating solutions. In one or more embodiments, the lower collimator plate 242 is positioned in between the pixelated anode assembly 212 and the membrane 220 in the anolyte compartment 224. The lower collimator plate 242 includes a body having walls 244 defining and separating elongated conduits 246. The elongated conduits 246 are generally positioned adjacent to each other and have parallel or substantially parallel axes. In one or more embodiments, openings of the elongated conduits 246 are sized to fit within the boundary defined by a pixel of the pixelated anode assembly 212. In one or more other embodiments, the lower collimator plate 242 is replaced by a bundle of separated tubes.

In one or more embodiments the lower collimator plate 242 is positioned below the upper collimator plate 232 such that the longitudinal axes of the elongated conduits 246 of the lower collimator plate 242 are aligned with the longitudinal axes of the elongated conduits 236 of the upper collimator plate 232. Alignment of the longitudinal axes of the elongated conduits 246 of the lower collimator plate 242 and the longitudinal axes of the elongated conduits 236 of the upper collimator plate 232 generally ensures that the electric fields and plating current flow from each of the pixels of the pixelated anode assembly 212 is substantially vertical and has minimal horizontal movement or dispersion, and the elongated conduits 236, 246 prevent the electric field and plating current flow from traveling substantially horizontally or dispersing while traveling therethrough.

Although the upper collimator plate 232 and the lower collimator plate 242 are shown as separate units, in some embodiments where the membrane 220 is not present, the collimator may be a single unit.

In one or more embodiments, the plating cell 202 further includes a pattern mask diffuser 250 disposed between the membrane 220 and the substrate 214. The pattern mask diffuser 250 provides a pattern mask that is used to further control the formation of the electric fields and plating current flow from each of the pixels of the pixelated anode assembly 212 to the die pattern formed on the surface of the substrate. The uniformity of plating conditions across the substrate 214 will therefore be enhanced by use of the pattern mask diffuser 250, as discussed further below. In one or more embodiments, the pattern mask diffuser 250 is designed with apertures having dimensions of from about 0.1 microns to about 500 microns. The apertures can include any shape, such as a square, rectangular, circular, hexagonal, slot or other desirable shape. The vertical height of the pattern mask diffuser 250 can be altered to provide desired fluid flow characteristics therethrough. For example, a thicker pattern mask diffuser 250 with the same aperture dimensions will provide an increased resistance to fluid flow through the pattern mask diffuser 250 to provide a more restricted fluid flow through the pattern mask diffuser 250 having similar aperture dimensions. The pattern mask diffuser 250 is generally formed of an insulating material, such as plastic, glass, ceramic, metal covered with an insulative coating, polymer, or composite material.

In one or more embodiments, the pattern mask diffuser 250 is translatable or movable in the X-Y direction. Movement of the pattern mask diffuser 250 in the X-Y direction relative to the substrate 214 can control the flow of plating fluid to targeted areas of the substrate 214.

The plating cell 202 further includes a plating head assembly 270 for supporting the substrate 214 in a face-down orientation. The plating head assembly 270 includes a plating head 272 and a substrate support 274 for supporting the substrate 214 in a face-down orientation. The plating head assembly 270 is capable of rotational movement for rotating the substrate 214 during plating operations. The plating head assembly 270 is capable of up/down movement in the z-direction for lowering the substrate 214 into engagement with one or more components of the plating cell 202, for example, the plating solution and removing the substrate 214 from engagement with the one or more components of the plating solution. The plating head assembly 270 may be translatable or capable of movement in the X-Y plane for adjusting the position of the substrate 214 relative to the field lines.

The plating head assembly 270 may further include a contact ring (not shown) disposed on the substrate support 274, which is provided to hold the substrate 214 and may have a plurality of contact fingers for making electrical contact with a conductive layer, such as a metal seed layer, formed on the surface of the substrate 214 that includes the die pattern regions D1-D8. In FIG. 2, the substrate 214 is positioned in a face-down orientation so that the die pattern regions D1-D8 are positioned to contact an electrolyte that flows from the catholyte compartment into a plating region 211, and then to the lower facing surface of the substrate 214. The plating head assembly 270 may include a rotor (not shown) for rotating the substrate 214 and contact ring during processing. The plating head assembly 270 may be movable to position the substrate support 274 into a processing position in the plating cell 202, where the metal layers within the die pattern regions are in contact with electrolyte in the plating cell 202.

The plating cell 202 may further include a thief electrode 280. The thief electrode 280 can be positioned adjacent to the substrate 214 and have a shape corresponding to the edges of the substrate 214. The thief electrode 280 may be biased at the same polarity as the substrate 214 such that the thief electrode 280 modifies the electric field in the perimeter region of the substrate 214. Accordingly, the thief electrode 280 reduces the plating rate at the perimeter of the substrate 214 to compensate for the edge effect.

The cathode formed by the biased die pattern formed on the surface of the substrate 214 and the pixelated anode assembly 212 are electrically connected to a power supply (not shown). In a plating operation, the cathode has a negative charge so that copper ions in the plating solution (catholyte) are reduced at the cathode forming plated copper metal on the plating surface of the substrate 214.

The electroplating system 200 may further include a system controller 290. The system controller 290 may be provided and coupled to various components of the electroplating system 200 to control the operation thereof. The system controller 290 can be a single controller that controls the entire electroplating system 200, or multiple controllers that control individual portions of the electroplating system 200. For example, the electroplating system 200 may include separate controllers for each of the pixelated anode assembly 212, the pattern mask diffuser 250, and the fluid supply system.

In some embodiments, the system controller 290 includes a central processing unit (CPU) 292, a memory 294, and support circuits 296. The system controller 290 may control the electroplating system 200 directly, or via computers (or controllers) associated with particular process chamber and/or support system components.

The system controller 290 may be one of any form of general-purpose computer processor that can be used in an industrial setting for controlling various chambers and sub-processors. The memory 294 or computer readable medium of the system controller 290 may be one or more of readily available memory such as random access memory (RAM), read only memory (ROM), floppy disk, hard disk, optical storage media (e.g., compact disc or digital video disc), flash drive, or any other form of digital storage, local or remote. The memory 294 can retain an instruction set that is operable by the processor (CPU 292) to control parameters and components of the electroplating system 200.

The support circuits 296 are coupled to the CPU 292 for supporting the processor in a conventional manner. These circuits include cache, power supplies, clock circuits, input/output circuitry and subsystems, and the like. One or more processes may be stored in the memory 294 as software routine that, when executed or invoked by the processor, causes the processor to control the operation of the electroplating system 200 or individual processing chambers in the manner described herein. The software routine may also be stored and/or executed by a second CPU (not shown) that is remotely located from the hardware being controlled by the CPU 292.

Some or all of the processes and methods of the present disclosure may also be performed in hardware. As such, the process may be implemented in software and executed using a computer system, in hardware as, e.g., an application specific integrated circuit or other type of hardware embodiment, or as a combination of software and hardware. The software routine, when executed by the processor, transforms the general purpose computer into a specific purpose computer (controller) that controls the chamber operation such that the processes are performed.

In some embodiments, the system controller 290 has one or more configurations to execute individual processes or sub-processes to perform the method 100. The system controller 290 can be connected to and configured to operate intermediate components to perform the functions of the methods. For example, the system controller 290 can be connected to and configured to control one or more of valves, actuators, motors, slit valves, vacuum control, or other components.

Processes may generally be stored in the memory of the system controller 290 as a software routine that, when executed by the processor, causes the process chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware as, for example, an application specific integrated circuit or other type of hardware embodiment, or as a combination of software and hardware. The software routine, when executed by the processor, transforms the general-purpose computer into a specific purpose computer (controller) that controls the chamber operation such that the processes are performed.

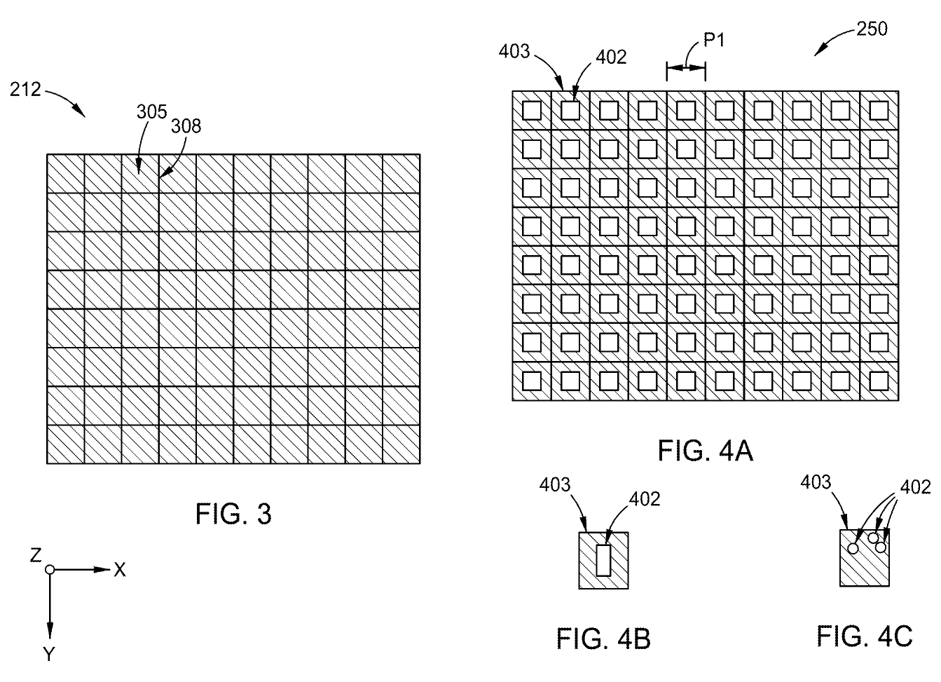

FIG. 3 illustrates a schematic plan view of a pixelated anode assembly, for example, the pixelated anode assembly 212, in accordance with one or more embodiments of the present disclosure. In one or more embodiments, the pixelated anode assembly 212 includes a plurality of individual anode members 305 (e.g., 80 anode members shown in FIG. 3) that cooperatively form the pixelated anode assembly 212. For example, embodiments may include between about 20 and about 200 individual pixelated anode members 305 that collectively form the pixelated anode assembly 212. The individual anode members 305 may be manufactured from a soluble conductive material, such as copper for a copper electrochemical plating system, or from another material that is soluble in an electrochemical plating solution. Alternatively, the individual anode members 305 may be manufactured from an insoluble conductive material, such as platinum, titanium, or other insoluble metals amenable to electrochemical plating solutions. Further, the conductive material of the anode members 305 may be coated with another conductive material, such as platinum, for example. The individual anode members 305 may be manufactured as square shaped (in plan view) conductive members, wherein an electrically insulative spacer 308 may be positioned between the respective square shaped anode members 305 to electrically isolate the anode members 305 from each other. The electrically insulative spacers 308 generally have a thickness of less than about 3 mm, and more particularly, less than about 1 mm, so that the surface area on the anode surface that is not electrically active is minimized, as inactive surface area on the anode has been shown to facilitate plating uniformity problems, such as the problems associated with concentric anode configurations where there is a small non-active space between the concentric rings of the anode member. The electrically insulative spacers 308 used in the pixelated anode assembly 212 may be made from any insulative or dielectric material that is not reactive with electrochemical plating solutions, such as, PVDF, Teflon®-type materials, plastics, insulative oxides, anodized materials, the same material as the anode, etc.

Each of the respective anode members 305 is independently biasable and also generally in electrical communication with an anodic terminal of a power supply (as illustrated in FIG. 2). The electrical power or current applied to each of the respective anode members 305 may be individually controlled or regulated by a controller (not shown). The controller may be used to adjust the resistance of a variable resistor (not shown), for example, positioned in series electrical connection between each individual anode member 305 and the power supply. The controller may be a microprocessor type controller configured to control a processing sequence, as is generally known in the art. The controller may be modified, however, to allow for control of the individual anode members 305. The anode members 305 may further be controlled in groups or banks, e.g., regions of the pixelated anode assembly 212, such as a group of anode members 305 in the central portion of the pixelated anode assembly 212 and a surrounding group of anode members 305 near the perimeter of the pixelated anode assembly 212. The controlled banks or groups of anode members 305 may be in any shape, size, or number.

A method of electroplating may include positioning a substrate 214 in a face-down orientation opposite a pixelated anode assembly 212 and biasing individual anode members 305 of the pixelated anode assembly 212 to direct plating current toward selected regions of the substrate 214. In some embodiments, power delivered to the individual anode members 305 is varied independently during plating to compensate for differences in pattern density across the substrate 214. In some embodiments, power is delivered to groups of anode members 305 or banks of anode members 305.

FIG. 4A illustrates a schematic plan view of a pattern mask diffuser, for example, the pattern mask diffuser 250, in accordance with one or more embodiments of the present disclosure. The pattern mask diffuser 250 includes an array of pixel features 403 (e.g., 80 pixel features in FIG. 4) that each include one or more aperture(s) 402 that are formed therein. In one or more embodiments, the pattern mask diffuser 250 includes a plurality of aperture(s) 402 that cooperatively form the pattern mask diffuser 250. For example, embodiments may include between about 20 and about 200 individual apertures 402 that collectively form the pattern mask diffuser. In one or more embodiments, the number of aperture(s) 402 generally corresponds to the number of anode members 305 in the pixelated anode assembly 212. The pattern mask diffuser 250 is generally formed of an insulating material, such as plastic, glass, ceramic, metal covered with an insulative coating, polymer, or composite material.

The apertures 402 in the pattern mask diffuser 250 are used to preferentially allow the regions of the die pattern positioned vertically adjacent to the aperture 402 at an instant in time during a plating process to receive a significant portion of the plating current versus regions of the pattern mask diffuser 250 positioned between laterally adjacent apertures 402. Thus, in some embodiments, the pattern mask diffuser 250 is used as an electric field shield.

FIGS. 4B-4C are schematic close-up plan views of a pixel feature 403 of the pattern mask diffuser in accordance with one or more embodiments of the present disclosure. The one or more aperture(s) 402 within each of the pixel features 403 of the pattern mask diffuser 250 can include one or more openings that extend through the pattern mask diffuser 250. In one example, as shown in FIG. 4A the one or more aperture(s) 402 within a pixel feature 403 include a single square shaped opening. In another example, as shown in FIG. 4B, the one or more aperture(s) 402 within a pixel feature 403 can include a single rectangular shaped opening. In another example, as shown in FIG. 4C, the one or more aperture(s) 402 within a pixel feature 403 can include a pattern of circular shaped openings. In some embodiments, a pattern of openings within each pixel feature 403 of the pattern mask diffuser 250 a similarly oriented and aligned. In some other embodiments, a pattern of openings within two or more pixel features 403 within the array of pixel features 403 in a pattern mask diffuser 250 differ.

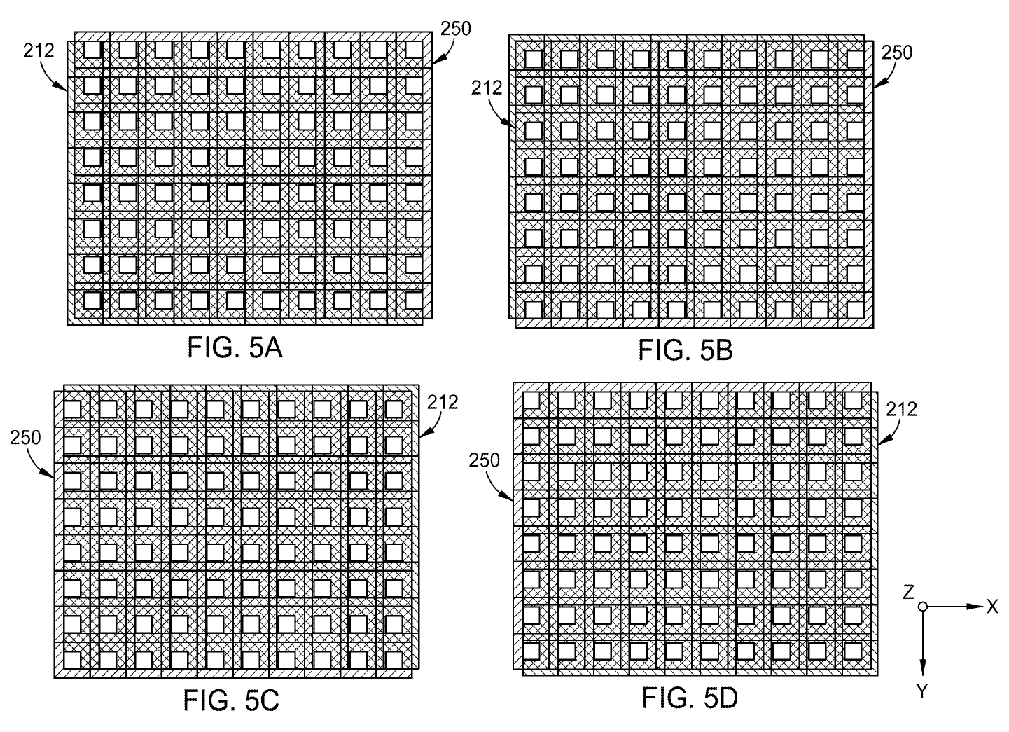

FIGS. 5A-5D illustrate schematic plan views of the X-Y movement of a diffuser assembly, for example, the pattern mask diffuser 250 relative to a pixelated anode assembly, for example, the pixelated anode assembly 212, during various stages of a plating process in accordance with one or more embodiments of the present disclosure. The X-Y movement of the pattern mask diffuser 250 relative to the pixelated anode assembly 212, which may be stationary, and optionally the movement of the substrate 214 may be coordinated in time with the power delivered to each corresponding anode member 305. FIGS. 5A-5D depict the sequence of movement the pattern mask diffuser 250 relative to the pixelated anode assembly 212 over a sequence of time frames. The sequence of movement and dwell times after each movement may be performed and controlled by software. For example, at time frame one (not shown), the aperture(s) 402 of the pattern mask diffuser 250 are centered over a corresponding anode member 305 of the pixelated anode assembly 212. Referring to FIG. 5A, at time frame two, the aperture(s) 402 of the pattern mask diffuser 250 are moved and positioned over the upper right portion of the corresponding anode member 305 of the pixelated anode assembly 212. Referring to FIG. 5B, at time frame three, the aperture(s) 402 of the pattern mask diffuser 250 are moved and positioned over the lower right portion of the corresponding anode member 305 of the pixelated anode assembly 212. Referring to FIG. 5C, at time frame four, the aperture(s) 402 of the pattern mask diffuser 250 are moved and positioned over the lower left portion of the corresponding anode member 305 of the pixelated anode assembly 212. Referring to FIG. 5D, at time frame five, the aperture(s) 402 of the pattern mask diffuser 250 are moved and positioned over the upper left portion of the corresponding anode member 305 of the pixelated anode assembly 212. At time frame six (not shown) the aperture(s) 402 of the pattern mask diffuser 250 are re-centered over the corresponding anode member 305 of the pixelated anode assembly 212. Time frames one to five constitute a cycle and the cycle may be repeated any number of times. Also, it should be understood that the sequence of movement depicted in FIGS. 5A-5D is one example, and that other sequences of movement are also contemplated.

A method of electroplating may further include positioning a pattern mask diffuser 250 between the substrate 214 and the pixelated anode assembly 212 and translating the pattern mask diffuser 250 in an X-Y plane during plating. In some embodiments, the pattern mask diffuser 250 is translated through a sequence of offset positions relative to corresponding anode members 305 during a plating cycle. In some embodiments, translation of the pattern mask diffuser 250 is coordinated in time with variation of power delivered to individual anode members 305 or groups of anode members 305.

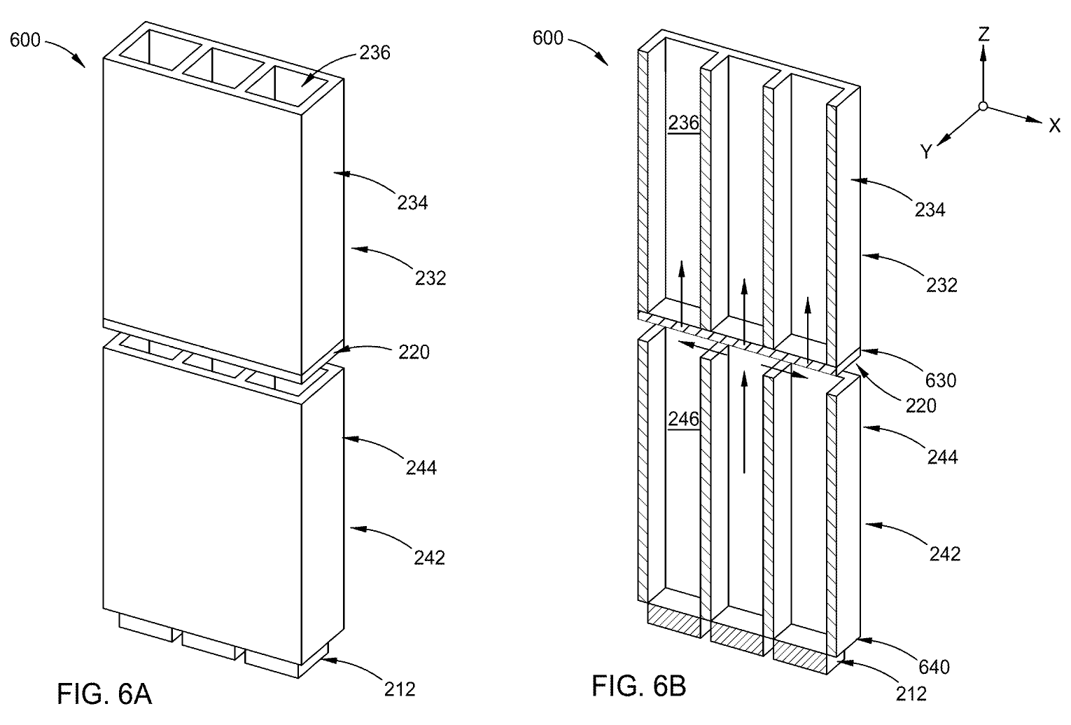

FIGS. 6A-6B illustrate isometric views of a portion of an electroplating system 600 in accordance with one or more embodiments of the present disclosure. The portion of the electroplating system 600 may be part of the electroplating system 200. FIGS. 6A-6B show one example of the positioning of the upper collimator plate 232 and the lower collimator plate 242 relative to the membrane 220 and the pixelated anode assembly 212. Positioning of a lower surface 630 of the upper collimator plate 232 close to the membrane 220 also operates to minimize horizontal electric field movement between adjacent elongated conduits 236 that form part of the upper collimator plate 232 and the lower collimator plate 242. For example, in the plating cell 202, the membrane 220 operates to transmit the electric field emitted from the pixelated anode assembly 212 therethrough so that the electric field can travel to the die pattern formed on the substrate 214 to facilitate the electrochemical plating process thereon. Positioning the lower surface 630 of the upper collimator plate 232 as close as possible to the membrane 220 operates to capture the electric field traveling through the membrane 220 before the electric field is able to travel horizontally between adjacent elongated conduits 236. Once the electric field is captured by the elongated conduits 236 of the upper collimator plate 232, the electric field is vertically channeled toward the plating surface of the substrate 214. Positioning a lower surface 640 of the lower collimator plate 242 closer to the pixelated anode assembly 212 further assists with minimizing the lateral electric field divergence into adjacently positioned elongated conduits 236 in the upper collimator plate 232 and the lower collimator plate 242.

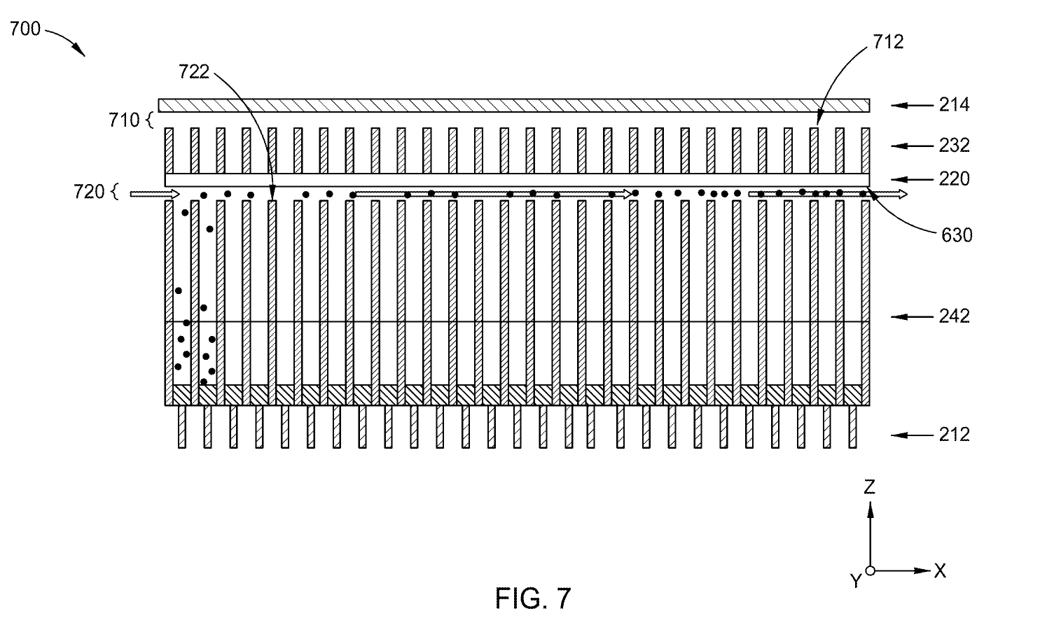

FIG. 7 illustrates a schematic side view of a portion of an electroplating system 700 in accordance with one or more embodiments of the present disclosure. The portion of the electroplating system 700 may be part of the electroplating system 200. The portion of the electroplating system 700 shows one example of the positioning of the upper collimator plate 232 and the lower collimator plate 242 relative to the substrate 214, the membrane 220, and the pixelated anode assembly 212. The membrane 220 depicted in FIG. 7 is a flat or planar membrane. The pixelated anode assembly 212 depicted in FIG. 7 includes an inert anode and post for each pixel of the pixelated anode assembly 212. During plating operations, the inert anode generates gas or bubbles. The lower surface 630 of the upper collimator plate 232 contacts an upper surface of the membrane 220. A catholyte flow gap 710 is formed between an upper surface 712 of the upper collimator plate 232 and the plating surface of the substrate 214. In one or more embodiments, the catholyte flow gap 710 may be in a range from about 1 millimeter to about 6 millimeters or in a range from about 2 millimeters to about 5 millimeters. Not to be bound by theory but it is believed that when the upper surface 712 of the upper collimator plate 232 is positioned within about 5 millimeters or less from the plating surface, that horizontal electric field movement is essentially eliminated because there is little space or area for the electric field to disperse horizontally. An anolyte flow gap 720 is formed between an upper surface 722 of the lower collimator plate 242 and a lower surface of the membrane. The anolyte flow gap 720 is large enough to allow for cross flow to clear bubbles generated by the inert anode to escape but small enough to reduce or eliminate horizontal electric field movement. Since bubbles can affect the quality of the plated material, it is preferable to prevent bubbles from entering the catholyte compartment. In one or more embodiments, the anolyte flow gap 720 is in a range from about 0.5 millimeters to about 3 millimeters or in a range from about 1 millimeter to about 2 millimeters.

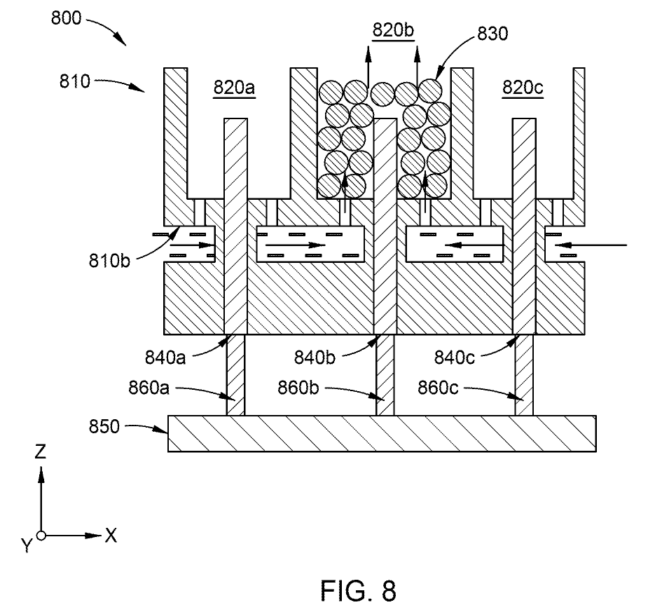

FIG. 8 illustrates a schematic side view of a lower portion of a pixelated anode assembly 800 in accordance with one or more embodiments of the present disclosure. The pixelated anode assembly 800 may be the pixelated anode assembly 212. The pixelated anode assembly 800 includes a body 810 that defines a plurality of pockets 820a-c. Each pocket 820a-c defines a pixel of the pixelated anode assembly 800. For example, referring to FIG. 3, the pockets 820a-c each define a square shaped anode member, for example, the square shaped anode members 305, and the body 810 is the electrically insulative spacer 308 positioned between the respective square shaped anode members 305. The body 810 may be formed from injection molded polypropylene. Each pocket 820a-c holds a consumable copper source, for example, copper balls 830, for supplying copper to the anolyte solution. In some embodiments, the consumable copper source within each anode member 305 can include a solid block of copper. The copper balls 830 provide for easy pixel replenishment. The bottom surface 810b of the body 810 includes a fluid plenum that includes one or more inlets for flowing anolyte from the bottom of each pocket 820a-c or pixel. Each pocket 820a-c includes a platinum pin 840a-c that is configured to contact the consumable portion of the anode member 305. Each platinum pin 840a-c is electrically coupled with a printed circuit board (PCB) 850 via a spring-loaded pin 860a-c or pogo pin. Power connection of the platinum pin 840a-c to the PCB via the spring-loaded pin 860a-c provides for easy alignment, no damage and/or tolerance issues.

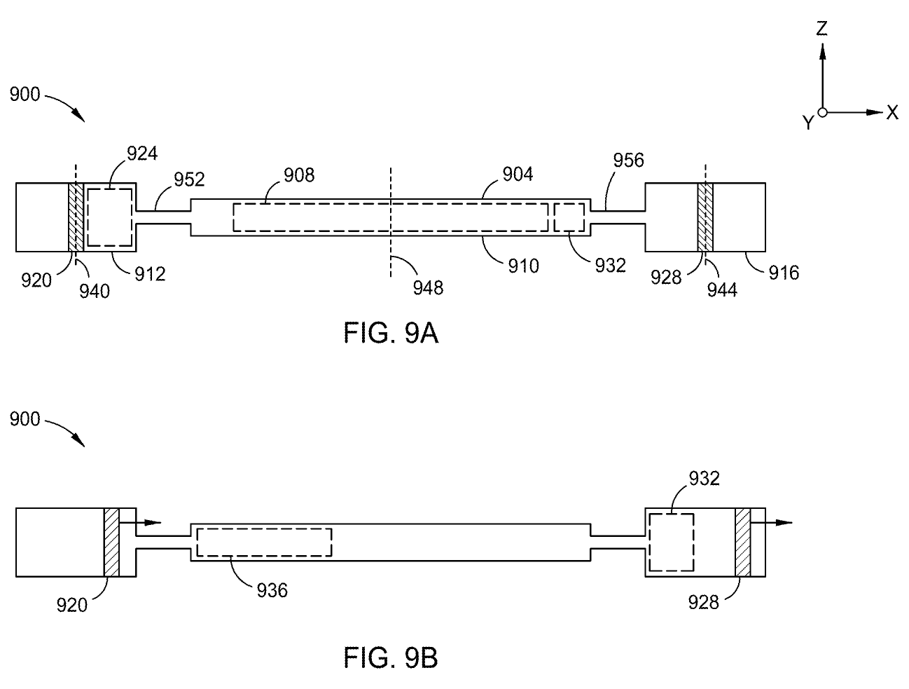

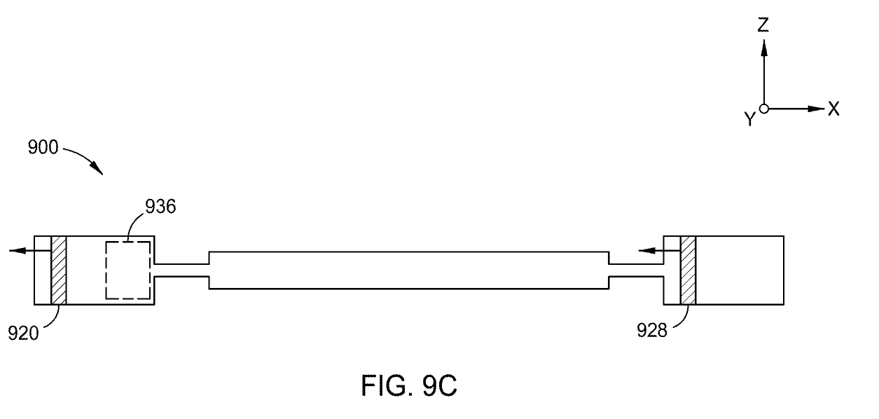

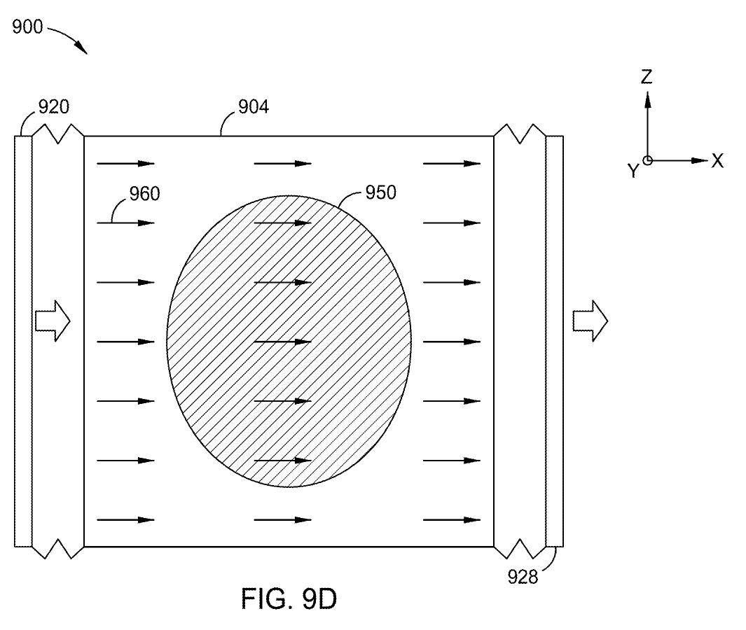

FIGS. 9A-9D illustrates a schematic side view of a portion of an electroplating system in accordance with one or more embodiments of the present disclosure. The electroplating system 200 of FIG. 2 may be modified to include a system with oscillating shear flow. FIG. 9A shows an example system 900 for electroplating, which may be used in combination with any of the components depicted in FIGS. 2-8. System 900 includes a vessel 904 configured to hold a first portion 908 of a liquid electrolyte. Vessel 904 may be the plating cell 202 or the vessel 203 in FIG. 2. The electroplating of the substrate may occur in vessel 904. System 900 may also include a substrate holder configured for holding a substrate in vessel 904. The substrate may be held as described in FIG. 2. Vessel 904 may include a channel floor 910, which may be on the opposite side of a channel as the substrate holder. System 900 may further include a first reservoir 912 in fluid communication with vessel 904. System 900 may also include a second reservoir 916 in fluid communication with vessel 904. First reservoir 912 may be in fluid communication with second reservoir 916. System 900 may include a first mechanism 920 configured to expel a second portion 924 of the liquid electrolyte from first reservoir 912 into vessel 904. System 900 may also include a second mechanism 928 configured to take in a third portion 932 of the liquid electrolyte from vessel 904 into second reservoir 916 when second portion 924 is expelled from first reservoir 912.

First portion 908, second portion 924, and third portion 932 are simplified to illustrate how the liquid electrolyte may be moved between first reservoir 912, second reservoir 916, and vessel 904. Flow dynamics are more complicated than the illustration in FIG. 9A. The illustrated portions of the liquid electrolyte would not necessarily be moved between the different locations. The volume of first reservoir 912 may be greater than or equal to volume of vessel 904. As a result of this volume relationship, one move of first mechanism 920 to fully expel first reservoir 912 may result in a full exchange of the electrolyte within vessel 904. Similarly, the volume of second reservoir 916 may be greater than or equal to volume of vessel 904. The volume of first reservoir 912 may equal the volume of second reservoir 916.

Second mechanism 928 may be configured to expel third portion 932 of the liquid electrolyte from second reservoir 916 into vessel 904. First mechanism 920 may be configured to take in a fourth portion 936 of the liquid electrolyte from vessel 904 into first reservoir 912 when third portion 932 of the liquid electrolyte is expelled from second reservoir 916.

First mechanism 920 may be configured to oscillate between expelling and taking in liquid electrolyte from first reservoir 912. Second mechanism 928 may be configured to oscillate between expelling and taking in liquid electrolyte from second reservoir 916.

First mechanism 920 may include a first sliding element. The first sliding element may be configured to move within first reservoir 912. Second mechanism 928 may include a second sliding element. The second sliding element may be configured to move within second reservoir 916. First mechanism 920 or second mechanism 928 may be a piston. The mechanism may be any combination of volume expansion and contraction devices to shuffle flow back and forth across the chamber or substrate. For example, moving endwalls with bellows could be employed rather than sliding elements.

A cross-sectional area of the first sliding element may be equal or substantially equal to a cross-sectional area of a first space defined by first reservoir 912. The cross-sectional area of the first sliding element and the cross-sectional area of the first space may both be areas in a single plane 940. For example, the first space defined by the first reservoir may be a cylinder or cylindrical in shape. The first sliding element may be a circle or circular in shape. The circle may move within the cylinder. Seals or O-rings may be present on the first sliding element and between the first sliding element and the first reservoir to allow for movement of the first sliding element to create a pressure gradient. Similarly, the cross-sectional area of the second sliding element may be equal to the cross-sectional area of a second space defined by second reservoir 916. The cross-sectional area of the second sliding element may be analogous to any cross-sectional area of the first sliding element, and the cross-sectional area of the second space may be analogous to any cross-sectional area of the first space. First mechanism 920 and second mechanism 928 may be sliding elements that move within rectangular cross sections similar to vessel 904 or larger.

First mechanism 920 may be configured to expel second portion 924 of the liquid electrolyte in a direction. The direction may be from first reservoir 912 into vessel 904. For example, in FIG. 9B, the direction is illustrated as left to right. First mechanism 920 may be configured to move in the direction to expel second portion 924 of the liquid electrolyte. Second mechanism 928 may be configured to move in the same direction to take in third portion 932 of the liquid electrolyte. First mechanism 920 and second mechanism 928 may move in sync.

FIG. 9C shows movement of first mechanism 920 and second mechanism 928 in the opposite direction when second mechanism 928 expels liquid electrolyte and first mechanism 920 takes in liquid electrolyte. First mechanism 920 takes in fourth portion 936 of the liquid electrolyte. In FIG. 9C, the direction is shown as right to left. The movement of first mechanism 920 and second mechanism 928 may cycle through these figures, such that first mechanism 920 and second mechanism 928 are in the positions in FIG. 9A and then FIG. 9B following FIG. 9C.

FIG. 9D shows a top view of system 900. Substrate 950 is shown in the middle of vessel 904. First mechanism 920 and second mechanism 928 are shown connected to bellows. First mechanism 920 and second mechanism 928 may be moving endwalls of a channel. Vessel 904 may be considered as including a flow channel with substrate 950 forming an upper wall and the floor of the vessel (the channel floor 910) forming the lower wall. Arrows, such as arrow 960, indicate the direction of flow within vessel 904. The flow direction across the wafer is shown as substantially in only one direction, regardless of the position (e.g., top of FIG. 9D to bottom of FIG. 9D) on the wafer. This flow may be a result of a wide channel for the flow or several channels from first mechanism 920 across the diameter of the wafer. This directional flow across the wafer may not result from a single channel less than the diameter of the wafer.

First mechanism 920 may be connected to second mechanism 928 such that movement by first mechanism 920 results in movement by second mechanism 928. For example, a rigid bar may physically connect first mechanism 920 to second mechanism 928. First mechanism 920 may only move when second mechanism 928 moves. The rigid bar may be in mechanical communication with an actuator, motor (e.g., a stepper motor, linear motor, rotary motor with linkages, pneumatic), spring, or other suitable device. In some embodiments, first mechanism 920 may not be physically connected to second mechanism 928. In some embodiments, if system 900 is sealed, one of first mechanism 920 and second mechanism 928 may be the driver and the other mechanism would be the follower, driven by the internal pressure in the vessel created by first mechanism 920. A processor may be configured to control the movement of first mechanism 920. A processor may be configured to control the movement of second mechanism 928. Movement of the first mechanism or the second mechanism may be by an actuator, a motor (e.g., a stepper motor), spring, or other suitable device. In some embodiments, first mechanism 920 may move independently of second mechanism 928. For example, second mechanism 928 may move in the same direction as first mechanism 920 slightly before or after first mechanism 920 moves. A delay between the movements of the mechanisms may be used to optimize flow characteristics. If system 900 is sealed, movements of the mechanisms may be synchronized.

System 900 may include no mechanisms configured to agitate the liquid electrolyte located within vessel 904. For example, system 900 may not include paddles that move to agitate the liquid electrolyte within vessel 904, including in the area where the substrate is processed. The area where the substrate is processed may include a cylinder or other geometry circumscribing the substrate within vessel 904. For example, the area may exclude portions of vessel 904 outside a cylinder-like volume extending from the edge of the substrate. The processing area may exclude portions of the electrolyte where ions are too far from the substrate to affect plating of the substrate. First mechanism 920 and second mechanism 928 may be located outside the edge of the substrate.

System 900 may be configured such that when first mechanism 920 expels second portion 924 from first reservoir 912 into vessel 904, no portion of the liquid electrolyte exits the vessel 904 other than to second reservoir 916. Similarly, system 900 may be configured such that when second mechanism 928 expels third portion 932 from second reservoir 916 into vessel 904, no portion of the liquid electrolyte exits the vessel 904 other than to first reservoir 912. For example, vessel 904, first reservoir 912, and second reservoir 916 may be sealed so that no liquid may leak out of space contained by these components during expulsion of liquid electrolyte from either reservoir. The floor of vessel 904 (e.g., the channel floor 910) may be solid and not porous. The channel floor 910 may not allow liquid to pass through. However, the channel floor 910 may allow ions to pass through from an electrolyte plenum below the floor to allow ionic current to pass through the floor. The channel floor 910 may include an ionic membrane and may be made of Nafion. The channel floor 910 may include a rigid supporting structure or structures to immobilize the ionic membrane so that the ionic membrane does not disturb the oscillating flow. The rigid supporting structure may be a diffuser plate (e.g., a perforated plate made from a non-conducting material). The ionic membrane may be sandwiched between two rigid supporting structures.

The geometries of first reservoir 912, second reservoir 916, and vessel 904 may be configured so that movement of first mechanism 920 or second mechanism 928 provides a suitable velocity of the liquid electrolyte within vessel 904. The cross-sectional area of the reservoirs may be larger than the cross-sectional area of vessel 904 so that the velocity of the electrolyte will be faster in vessel 904 than in the reservoirs. First reservoir 912 may be characterized by a first cross-sectional area orthogonal to a plane including the substrate when the substrate is in the substrate holder. For example, the first cross-sectional area may be measured along plane 940. Second reservoir 916 may be characterized by a second cross-sectional area orthogonal to the plane including the substrate. For example, the second cross-sectional area may be measured along plane 944. Vessel 904 may be characterized by a third cross-sectional area orthogonal to the plane including the substrate. For example, the third cross-sectional area may be measured along plane 948. The third cross-sectional area may be less than the first cross-sectional area, and the third cross-sectional area may be less than the second cross-sectional area. The ratio of the first or second cross-sectional area to the third cross-sectional area may be from 1 to 1.5, from 1.5 to 2, from 2 to 5, from 5 to 10, or greater than 10. Ratios of areas and stroke length can be selected to drive fluid from first reservoir across vessel to second reservoir.

First reservoir 912 and second reservoir 916 may have equal or greater volumes than vessel 904. The ratio of the volume of first reservoir 912 or second reservoir 916 to the volume of vessel 904 may be from 1 to 1.5, from 1.5 to 2, from 2 to 5, from 5 to 10, or greater than 10. First reservoir 912 and second reservoir 916 may have a gap (e.g., the height in FIG. 9A) greater than the wafer gap of vessel 904. The wafer gap (e.g., distance between the wafer at the top of the vessel and floor of vessel) may be from 1 to 10 mm, including from 1 to 5 mm and from 5 to 10 mm.

FIG. 9A shows a first channel 952 between first reservoir 912 and vessel 904 and a second channel 956 between second reservoir 916 and vessel 904. The channels may not be straight and may be curved. In some embodiments, system 900 may not include channels, with the reservoirs being directly connected to vessel 904. The effect of first mechanism 920 and second mechanism 928 moving would be similar to sidewalls of a closed vessel (i.e., without reservoirs) moving. Although FIG. 9A shows first channel 952 to be narrower than the vessel 904, the first channel 952 may be the same width or wider than the vessel 904. The first channel 952 may have the same cross-sectional area as the vessel 904.

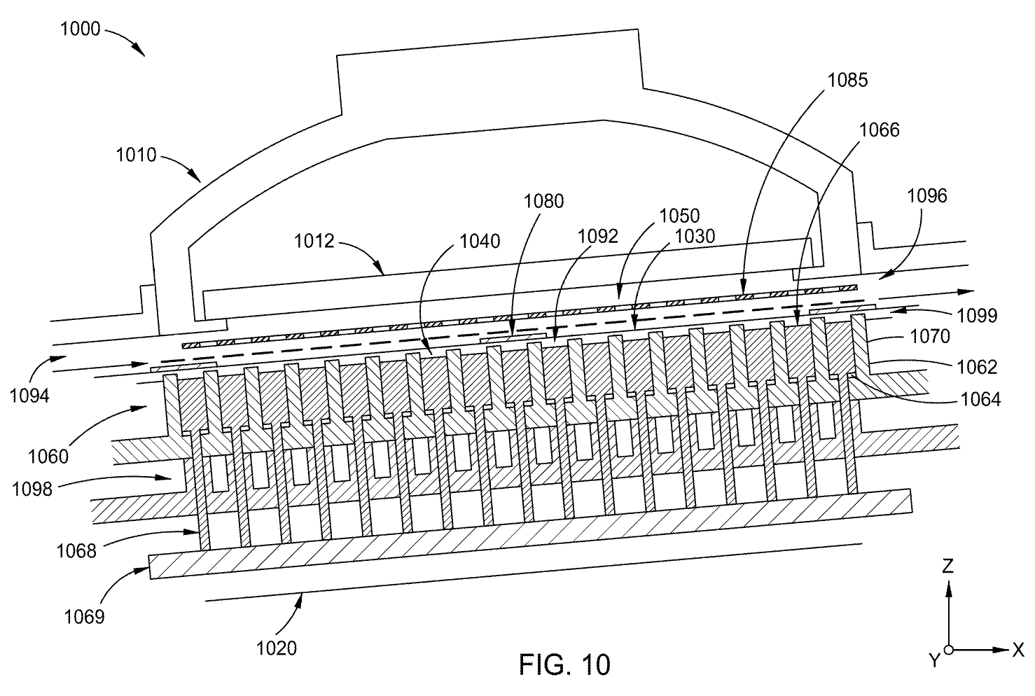

FIG. 10 illustrates a schematic side view of a portion of an electroplating system 1000 in accordance with one or more embodiments of the present disclosure. The electroplating system 1000 may be part of the electroplating system 200 described above. As shown in FIG. 10, the electroplating system 1000 includes a vessel 1020 defining a plating region and a substrate holder or plating head assembly 1010 positioned over the plating region and configured to hold a substrate 1012 in a face-down orientation relative to the vessel 1020. In some embodiments, the vessel 1020 and the substrate holder or plating head assembly 1010 are arranged such that the electroplating cell is tilted relative to horizontal during plating. In some embodiments, the electroplating cell is tilted by an angle in a range from about 1 degree to about 20 degrees relative to horizontal, or in a range from about 5 degrees to about 15 degrees relative to horizontal. In one example, the electroplating cell is tilted by about 5 degrees relative to horizontal, such that the substrate 1012 is also tilted during plating. In the illustrated embodiment, the X and Y directions define a lateral plane and the Z direction is normal to the lateral plane.

The electroplating system 1000 further includes an ionic membrane 1030 dividing the vessel 1020 into an anolyte compartment 1040 and a catholyte compartment 1050. A pixelated anode assembly 1060 is disposed in the anolyte compartment 1040 adjacent the ionic membrane 1030. In some embodiments, the pixelated anode assembly 1060 may be similar to the pixelated anode assembly 212 and/or the pixelated anode assembly 800 described above. In some embodiments, the pixelated anode assembly 1060 includes a plurality of individually biasable anode members arranged in an array. In some embodiments, the ionic membrane 1030 is supported on one or both sides thereof by one or more support structures. For example, a first support structure 1070 may be disposed adjacent one side of the ionic membrane 1030 in the anolyte compartment 1040. In some embodiments, a second support structure 1080 may additionally be disposed adjacent an opposite side of the ionic membrane 1030 in the catholyte compartment 1050. In some embodiments, the first support structure 1070 supports or defines a plurality of pixels of the pixelated anode assembly 1060.

In some embodiments, a pattern mask diffuser 1085 is disposed in the catholyte compartment 1050. The pattern mask diffuser 1085 may be similar to the pattern mask diffuser 250 described above. In some embodiments, the pattern mask diffuser 1085 is positioned above the second support structure 1080 when the second support structure 1080 is present. In some other embodiments, the pattern mask diffuser 1085 is positioned between the substrate 1012 and the ionic membrane 1030 when the second support structure 1080 is omitted. The pattern mask diffuser 1085 may include a body having an array of apertures formed therethrough and may be configured to shape electric-field distribution and plating-current flow toward selected regions of the substrate 1012. In some embodiments, the pattern mask diffuser 1085 is movable in the X-Y plane during plating, for example, in a manner similar to that described above with respect to the pattern mask diffuser 250.

In some embodiments, the first support structure 1070 comprises a collimator plate or other support member having a plurality of conduits, passages, apertures, or openings formed therethrough. In some embodiments, the second support structure 1080, when present, also comprises a collimator plate or other support member having a plurality of conduits, passages, apertures, or openings formed therethrough. The first support structure 1070, and the second support structure 1080 when present, may be configured to reduce horizontal electric-field dispersion as current travels between the pixelated anode assembly 1060 and the substrate 1012. In some embodiments, the first support structure 1070 and the second support structure 1080 are aligned with one another in a manner similar to that described above with respect to the upper collimator plate 232 and the lower collimator plate 242. In some embodiments, the pixelated anode assembly 1060, the ionic membrane 1030, the first support structure 1070, and, when present, the second support structure 1080 are stacked generally along the Z direction.

A flow system is configured to direct catholyte flow in a lateral direction across a substrate-facing side of the ionic membrane 1030 and toward the substrate 1012 during plating. In some embodiments, the flow system includes one or more pumps, such as a tangential flow pump, configured to produce crossflow or tangential flow of catholyte across the substrate 1012, for example, in a manner similar to the tangential flow arrangements described above. In some embodiments, catholyte is delivered to the catholyte compartment 1050 through a catholyte inlet 1094 and removed from the catholyte compartment 1050 through a catholyte outlet 1096. In some embodiments, the catholyte flow is directed through a gap defined between the substrate 1012 and the second support structure 1080 when the second support structure 1080 is present. In some embodiments, the catholyte flow is directed through a gap defined between the substrate 1012 and the ionic membrane 1030 when the second support structure 1080 is omitted, and the pattern mask diffuser 1085 is disposed within the catholyte flow path between the substrate 1012 and the ionic membrane 1030. The catholyte flow may promote mass transfer at the plating surface and improve plating uniformity across the substrate 1012.

In some embodiments, an anolyte flow gap 1092 is defined between the ionic membrane 1030 and the first support structure 1070 adjacent the pixelated anode assembly 1060. In some embodiments, anolyte is delivered to the anolyte compartment 1040 through an anolyte inlet 1098 and removed from the anolyte compartment 1040 through an anolyte outlet 1099. The anolyte flow gap 1092 may be sized to permit clearing of gas bubbles generated at the pixelated anode assembly 1060 during plating. In some embodiments, anolyte is directed through or around portions of the first support structure 1070 to sweep gas bubbles away from the ionic membrane 1030, thereby reducing the likelihood that bubbles enter the catholyte compartment 1050 or otherwise interfere with plating performance. In some other embodiments, such as embodiments employing inert anode material that generates bubbles during operation, gas evolution at the anode may itself provide agitation within the anolyte compartment 1040, and a separate refreshment flow may be reduced or omitted.

In some embodiments, the first support structure 1070 includes a body 1062 defining a plurality of pockets 1064. In some embodiments, each pocket 1064 contains an anode material 1066. The anode material 1066 may comprise a consumable metal source, such as copper balls or another consumable metal body. In some other embodiments, the anode material 1066 may comprise an inert anode structure, such as an inert anode and post associated with a corresponding pixel. In some embodiments, each anode member is electrically coupled through a respective pin assembly 1068 to a printed circuit board 1069. In some embodiments, the pin assembly 1068 includes a conductive pin and a spring-loaded pin, such as a pogo pin, to facilitate electrical connection and alignment. The use of the first support structure 1070, body 1062, pockets 1064, anode material 1066, pin assemblies 1068, and printed circuit board 1069 may allow individual powering of pixels within the pixelated anode assembly 1060. In embodiments employing consumable anode material, the arrangement may additionally facilitate replenishment of individual pixels. In some embodiments, the pin assembly 1068 and printed circuit board 1069 may be arranged in a manner similar to that described above with respect to FIG. 8.

In operation, the substrate 1012 is positioned opposite the pixelated anode assembly 1060 with the ionic membrane 1030 disposed therebetween. Current is delivered from the pixelated anode assembly 1060 toward the substrate 1012 while catholyte flow is directed across the substrate-facing side of the ionic membrane 1030 and toward the substrate 1012. Depending on the embodiment, the anolyte compartment 1040 may include directed anolyte flow, agitation produced by gas evolution at inert anodes, or both. In some embodiments, the electroplating system 1000 provides improved plating uniformity, reduced total thickness variation, improved co-planarity, improved bubble management, increased plating rate, increased throughput, or combinations thereof.

In some embodiments, a method of electroplating includes directing catholyte flow across a substrate-facing side of the ionic membrane 1030 and toward the substrate 1012 while directing anolyte flow within the anolyte compartment 1040 adjacent the pixelated anode assembly 1060. In some embodiments, the anolyte flow clears bubbles generated during plating. In some other embodiments, gas evolution at inert anodes associated with the pixelated anode assembly 1060 provides agitation within the anolyte compartment 1040.

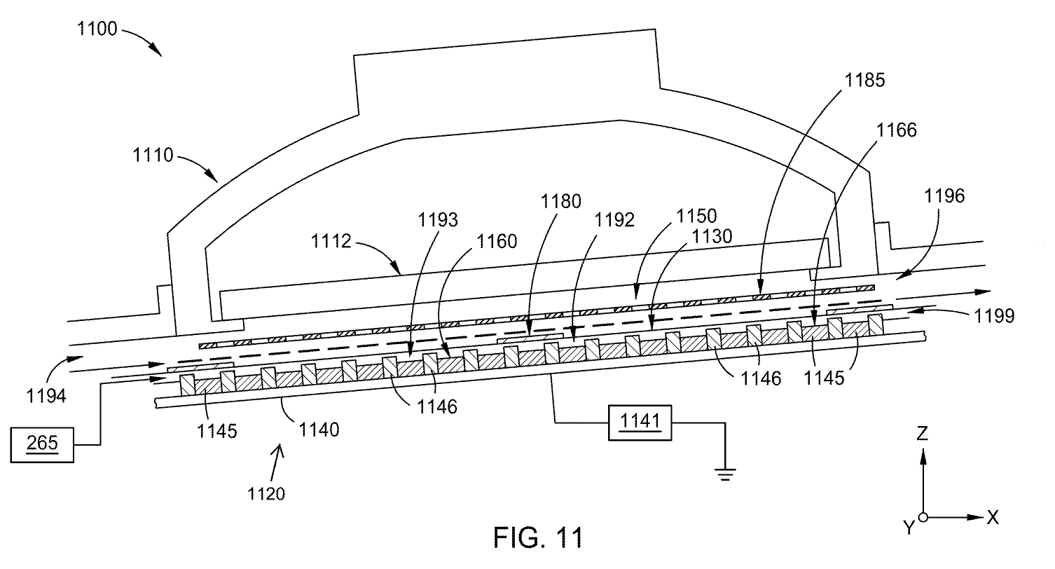

FIG. 11 illustrates a schematic side view of a portion of an electroplating system 1100 in accordance with one or more embodiments of the present disclosure. The electroplating system 1100 may be part of the electroplating system 200 described above. As shown in FIG. 11, the electroplating system 1100 includes a vessel 1120 defining a plating region and a substrate holder or plating head assembly 1110 positioned over the plating region and configured to hold a substrate 1112 in a face-down orientation relative to the vessel 1120. In some embodiments, the vessel 1120 and the substrate holder or plating head assembly 1110 are arranged such that the electroplating cell is tilted relative to the horizontal during plating. In some embodiments, the electroplating cell is tilted by an angle in a range from about 1 degree to about 20 degrees relative to horizontal, or in a range from about 5 degrees to about 15 degrees relative to horizontal. In one example, the electroplating cell is tilted by about 5 degrees relative to horizontal, such that the substrate 1112 is also tilted during plating. In the illustrated embodiment, the X and Y directions define a lateral plane, and the Z direction is normal to the lateral plane.

The electroplating system 1100 further includes an ionic membrane 1130 dividing the vessel 1120 into an anolyte compartment 1192 and a catholyte compartment 1150. A pixelated anode assembly 1160 is disposed in the anolyte compartment 1192 adjacent the ionic membrane 1130. In some embodiments, the pixelated anode assembly 1160 may be similar to the pixelated anode assembly 212 and/or the pixelated anode assembly 800 described above. In some embodiments, the pixelated anode assembly 1160 includes a plurality of individually biasable anode members arranged in an array and formed on a substrate 1140. In some embodiments, the ionic membrane 1130 is supported on one or both sides thereof by one or more support structures. For example, a first support structure 1146 may be disposed adjacent one side of the ionic membrane 1130 in the anolyte compartment 1192. In some embodiments, a second support structure 1180 may additionally be disposed adjacent an opposite side of the ionic membrane 1130 in the catholyte compartment 1150. In some embodiments, the first support structure 1146 supports or defines a plurality of pixels of the pixelated anode assembly 1160.

In some embodiments, a pattern mask diffuser 1185 is disposed in the catholyte compartment 1150. The pattern mask diffuser 1185 may be similar to the pattern mask diffuser 250 described above. In some embodiments, the pattern mask diffuser 1185 is positioned above the second support structure 1180 when the second support structure 1180 is present. In some other embodiments, the pattern mask diffuser 1185 is positioned between the substrate 1112 and the ionic membrane 1130 when the second support structure 1180 is omitted. The pattern mask diffuser 1185 may include a body having an array of apertures formed therethrough and may be configured to shape electric-field distribution and plating-current flow toward selected regions of the substrate 1112. In some embodiments, the pattern mask diffuser 1185 is movable in the X-Y plane during plating, for example, in a manner similar to that described above with respect to the pattern mask diffuser 250.

In some embodiments, the first support structure 1146 comprises a collimator plate or other support member having a plurality of conduits, passages, apertures, or openings formed therethrough. In some embodiments, the second support structure 1180, when present, also comprises a collimator plate or other support member having a plurality of conduits, passages, apertures, or openings formed therethrough. The first support structure 1146, and the second support structure 1180 when present, may be configured to reduce horizontal electric-field dispersion as current travels between the pixelated anode assembly 1160 and the substrate 1112. In some embodiments, the first support structure 1146 and the second support structure 1180 are aligned with one another in a manner similar to that described above with respect to the upper collimator plate 232 and the lower collimator plate 242. In some embodiments, the pixelated anode assembly 1160, the ionic membrane 1130, the first support structure 1146, and, when present, the second support structure 1180 are stacked generally along the Z direction.

A flow system is configured to direct catholyte flow in a lateral direction across a substrate-facing side of the ionic membrane 1130 and toward the substrate 1112 during plating. In some embodiments, the flow system includes one or more pumps, such as a tangential flow pump, configured to produce crossflow or tangential flow of catholyte across the substrate 1112, for example, in a manner similar to the tangential flow arrangements described above. In some embodiments, catholyte is delivered to the catholyte compartment 1150 through a catholyte inlet 1194 and removed from the catholyte compartment 1150 through a catholyte outlet 1196. In some embodiments, the catholyte flow is directed through a gap defined between the substrate 1112 and the second support structure 1180 when the second support structure 1180 is present. In some embodiments, the catholyte flow is directed through a gap defined between the substrate 1112 and the ionic membrane 1130 when the second support structure 1180 is omitted, and the pattern mask diffuser 1185 is disposed within the catholyte flow path between the substrate 1112 and the ionic membrane 1130. The catholyte flow may promote mass transfer at the plating surface and improve plating uniformity across the substrate 1112.

In some embodiments, an anolyte flow gap 1193 is defined between the ionic membrane 1130 and the first support structure 1146 adjacent the pixelated anode assembly 1160. In some embodiments, anolyte is delivered to the anolyte compartment 1192 through an anolyte inlet 1198 and removed from the anolyte compartment 1192 through an anolyte outlet 1199. The anolyte flow gap 1193 may be sized to permit clearing of gas bubbles generated at the pixelated anode assembly 1160 during plating. In some embodiments, anolyte is directed through or around portions of the first support structure 1146 to sweep gas bubbles away from the ionic membrane 1130, thereby reducing the likelihood that bubbles enter the catholyte compartment 1150 or otherwise interfere with plating performance. In some other embodiments, such as embodiments employing inert anode material that generates bubbles during operation, gas evolution at the anode may itself provide agitation within the anolyte compartment 1192, and a separate refreshment flow may be reduced or omitted.

In some embodiments, the first support structure 1146 includes a body 1162 defining a plurality of pockets formed between the first support structures 1146. In some embodiments, each pocket contains an anode pixel 1145. The anode pixel 1145 may comprise a non-consumable metal, such as platinum-coated titanium or another non-consumable metal that is compatible with the anolyte chemistry. In some embodiments, each anode member is formed on or electrically coupled to conductive layers formed within a substrate 1140. The substrate 1140 can include a silicon substrate or a PCB that includes conductive layers. The conductive layers are configured to receive and distribute a plating current from a plating power supply 1141 and deliver the current to each of the anode pixels 1145. The use of the first support structure 1146, anode pixel 1145, and the substrate 1140 are configured to allow individual powering of the plurality of pixels (e.g., anode pixels 1145) within the pixelated anode assembly 1160 by use of silicon controlled rectifiers (SCRs) (not shown) that are controlled by commands provided from the system controller 290. In one example, the plurality of pixels includes an array of greater than 100 pixels, such as greater than 500 pixels, or greater than 1000 pixels, or greater than 10,000 pixels, or greater than 50,000 pixels, or greater than 100,000 pixels, which are formed on the substrate 1140 by use of a patterning process on one or more of the conductive layers of the substrate or the PCB. In some embodiments, the pixels are formed on a silicon substrate using semiconductor processing techniques that form metalized features (e.g., titanium, tantalum, a noble metal (e.g., platinum), niobium, etc.) on the surface of the substrate 1140. The semiconductor processing techniques can include the deposition of metal and dielectric layers, patterning, and etching of the layers during the formation process. In some embodiments, the first support structure 1146, which can include an insulating material (e.g., Si, SiO₂, SiN, Al₂O₃, TiOₓ, etc.), can be formed on the surface of the substrate 1140 and between the pixels formed on the substrate’s surface by use of one or more semiconductor processing techniques, as shown in FIG. 11.

In operation, the substrate 1112 is positioned opposite the pixelated anode assembly 1160 with the ionic membrane 1130 disposed therebetween. Current is delivered to one or more of the anode pixels of the pixelated anode assembly 1160 and provided towards the substrate 1112 while catholyte flow is directed across the substrate-facing side of the ionic membrane 1130 and toward the substrate 1112. In some embodiments, the anolyte compartment 1192 will include directed anolyte flow from a pump 265 across the array of anode pixels 1145. In some embodiments, the electroplating system 1100 provides improved plating uniformity, reduced total thickness variation, improved co-planarity, improved bubble management, increased plating rate, increased throughput, or combinations thereof.

In some embodiments, a method of electroplating includes directing catholyte flow across a substrate-facing side of the ionic membrane 1130 and toward the substrate 1112 while directing anolyte flow within the anolyte compartment 1192 adjacent the pixelated anode assembly 1160. In some embodiments, the anolyte flow clears bubbles generated during plating. In some other embodiments, gas evolution at inert anodes associated with the pixelated anode assembly 1160 provides agitation within the anolyte compartment 1192.

The previously described implementations of the present disclosure have many advantages. Methods and apparatus for controlling uniformity of electrochemically deposited metals and alloys are provided. The method and apparatus achieve uniform electrochemical deposition of metals and alloys as well as electrophoretically deposited materials on wafers and square shaped substrates. The apparatus includes one or more of a pixelated anode assembly, a collimator with X-Y tuning, a pattern mask diffuser with X-Y adjustment, and the substrate with X-Y adjustment. However, the present disclosure does not necessitate that all the advantageous features and all the advantages need to be incorporated into every implementation of the present disclosure.

In the Summary and in the Detailed Description, and the Claims, and in the accompanying drawings, reference is made to particular features (including method operations) of the present disclosure. It is to be understood that the disclosure in this specification includes all possible combinations of such particular features. For example, where a particular feature is disclosed in the context of a particular aspect, implementation, implementation, or example of the present disclosure, or a particular claim, that feature can also be used, to the extent possible in combination with and/or in the context of other particular aspects and implementations of the present disclosure, and in the present disclosure generally.

Implementations and all of the functional operations described in this specification can be implemented in digital electronic circuitry, or in computer software, firmware, or hardware, including the structural means disclosed in this specification and structural equivalents thereof, or in combinations of them. Implementations described herein can be implemented as one or more non-transitory computer program products, i.e., one or more computer programs tangibly embodied in a machine readable storage device, for execution by, or to control the operation of, data processing apparatus, e.g., a programmable processor, a computer, or multiple processors or computers.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them. Processors suitable for the execution of a computer program include, by way of example, both general and special purpose microprocessors, and any one or more processors of any kind of digital computer.

Computer readable media suitable for storing computer program instructions and data include all forms of nonvolatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

The term “comprises” and grammatical equivalents thereof are used herein to mean that other components, ingredients, operations, etc. are optionally present. For example, an article “comprising” (or “which comprises”) components A, B, and C can consist of (i.e., contain only) components A, B, and C, or can contain not only components A, B, and C but also one or more other components. In addition, whenever a composition, an element or a group of elements is preceded with the transitional phrase “comprising” or grammatical equivalents thereof, it is understood that it is contemplated that the same composition or group of elements may be preceded with transitional phrases “consisting essentially of,” “consisting of,” “selected from the group of consisting of,” or “is” preceding the recitation of the composition, element, or elements and vice versa.

Where reference is made herein to a method comprising two or more defined operations, the defined operations can be carried out in any order or simultaneously (except where the context excludes that possibility), and the method can include one or more other operations which are carried out before any of the defined operations, between two of the defined operations, or after all of the defined operations (except where the context excludes that possibility).

When introducing elements of the present disclosure or exemplary aspects or implementation(s) thereof, the articles “a,” “an,” “the” and “said” are intended to mean that there are one or more of the elements.

The terms “comprising,” “including” and “having” are intended to be inclusive and mean that there may be additional elements other than the listed elements.

While the foregoing is directed to implementations of the present disclosure, other and further implementations of the disclosure may be devised without departing from the basic scope thereof, and the scope thereof is determined by the claims that follow.

What is claimed is:

1. An electroplating chamber, comprising:
a vessel;
a plating head assembly configured to hold a substrate in a face-down orientation;
a pixelated anode assembly comprising a plurality of individual anode members, each of the plurality of individual anode members being independently biasable;
a pattern mask diffuser disposed between the plating head assembly and the pixelated anode assembly, the pattern mask diffuser comprising a body having an array of apertures formed therethrough; and
an actuator configured to translate the pattern mask diffuser in an X-Y plane during plating.

2. The electroplating chamber of claim 1, further comprising a first collimator plate positioned to restrict horizontal dispersion of an electric field traveling from the pixelated anode assembly toward the plating head assembly.

3. The electroplating chamber of claim 2, further comprising an actuator configured to translate the first collimator plate in the X-Y plane.

4. The electroplating chamber of claim 2, further comprising a second collimator plate positioned between the pixelated anode assembly and the first collimator plate.

5. The electroplating chamber of claim 4, wherein:
the first collimator plate comprises a first plurality of elongated conduits;
the second collimator plate comprises a second plurality of elongated conduits; and
the second collimator plate is positioned below the first collimator plate such that longitudinal axes of the first plurality of elongated conduits are substantially aligned with longitudinal axes of the second plurality of elongated conduits.

6. The electroplating chamber of claim 4, further comprising an ionic membrane dividing the vessel into an anolyte compartment and a catholyte compartment, wherein the pixelated anode assembly is disposed in the anolyte compartment and the pattern mask diffuser is disposed in the catholyte compartment.

7. The electroplating chamber of claim 6, wherein the first collimator plate is disposed in the catholyte compartment and the second collimator plate is disposed in the anolyte compartment.

8. The electroplating chamber of claim 1, wherein the plating head assembly is movable in the X-Y plane relative to the pattern mask diffuser.

9. The electroplating chamber of claim 1, wherein the plating head assembly comprises a substrate support and a contact ring disposed on the substrate support.

10. The electroplating chamber of claim 1, further comprising a controller configured to coordinate translation of the pattern mask diffuser with power delivered to individual anode members or groups of anode members.

11. An electroplating chamber, comprising:
a vessel;
a substrate holder configured to hold a substrate in a face-down orientation over a plating region;
an ionic membrane dividing the vessel into an anolyte compartment and a catholyte compartment;
a pixelated anode assembly disposed in the anolyte compartment beneath the ionic membrane; and
a flow system configured to direct catholyte flow across a substrate-facing side of the ionic membrane and toward the substrate during plating.

12. The electroplating chamber of claim 11, further comprising a first support structure disposed in the anolyte compartment adjacent a lower side of the ionic membrane and a second support structure disposed in the catholyte compartment adjacent an upper side of the ionic membrane.

13. The electroplating chamber of claim 12, wherein the first support structure and the second support structure each comprise a collimator plate having a plurality of conduits configured to reduce horizontal electric-field dispersion.

14. The electroplating chamber of claim 11, wherein the flow system comprises a pump configured to produce tangential flow of catholyte across the substrate.

15. The electroplating chamber of claim 11, wherein an anolyte flow gap is defined between the ionic membrane and a support structure adjacent the pixelated anode assembly, the anolyte flow gap being sized to permit clearing of gas bubbles generated at the pixelated anode assembly.

16. The electroplating chamber of claim 11, wherein:
the plurality of anode members are disposed in pockets defined by a body;
each pocket contains a consumable metal source; and
each anode member is electrically coupled to a printed circuit board through a respective pin assembly.

17. The electroplating chamber of claim 11, wherein the vessel and the substrate holder are arranged such that the substrate is tilted relative to horizontal during plating.

18. A method of electroplating a substrate, comprising:
positioning a substrate in a face-down orientation opposite a pixelated anode assembly having a plurality of independently biasable anode members;
disposing a pattern mask diffuser having an array of apertures between the substrate and the pixelated anode assembly;
applying plating current through the pixelated anode assembly to deposit metal on the substrate; and
translating the pattern mask diffuser relative to the substrate in an X-Y plane during application of the plating current.

19. The method of claim 18, further comprising varying power delivered to individual anode members or groups of anode members in coordination with translation of the pattern mask diffuser.

20. The method of claim 18, wherein translating the pattern mask diffuser comprises moving the array of apertures through a sequence of offset positions relative to corresponding anode members during a plating cycle.
